(19) United States
(12) Patent Application Publication
(10) Pub. No.: US 2018/0069023 A1
(43) Pub. Date: Mar. 8, 2018

(54) DEPOSITION METHOD OF SILICON OXIDE THIN FILM AND MANUFACTURE METHOD OF LOW TEMPERATURE POLY-SILICON TFT SUBSTRATE

(71) Applicant: Wuhan China Star Optoelectronics Technology Co. Lt, Wuhan City (CN)

(72) Inventor: Weixin Ma, Wuhan City (CN)

(21) Appl. No.: 15/128,104

(22) PCT Filed: May 19, 2016
(86) PCT No.: PCT/CN2016/082670

§ 371 Date: Sep. 21, 2016

(30) Foreign Application Priority Data
Jan. 27, 2016 (CN) 201610054751.0

(51) Int. Cl. H01L 27/12; H01L 21/763; H01L 29/66; H01L 29/786

(52) U.S. Cl. CPC H01L 27/12; H01L 29/78675; H01L 29/66757; H01L 21/763

(57) ABSTRACT

The present invention provides a deposition method of a silicon oxide thin film and a manufacture method of a Low Temperature Poly-silicon TFT substrate. The present invention provides a deposition method of a silicon oxide thin film. The ultraviolet light is conducted to be the auxiliary energy of the reaction of the silicon oxide deposition. The ultra violet light is utilized to decompose the oxygen to be free oxygen, which reacts with the organic silane gas to generate silicon oxide, and thus to be deposited to form the silicon oxide thin film in the plasma free environment to prevent the surface of the silicon oxide thin film from the interface defect and surface damage formed by being impacted with the high energy plasma to raise the film formation quality of the silicon oxide thin film.

### FIELD OF THE INVENTION

The present invention relates to a display technology field, and more particularly to a deposition method of a silicon oxide thin film and a manufacture method of a Low Temperature Poly-silicon TFT substrate.

### BACKGROUND OF THE INVENTION

With the development of display technology, the flat panel device, such as Liquid Crystal Display (LCD) possesses advantages of high image quality, power saving, thin body and wide application scope. Thus, it has been widely applied in various consumer electrical products, such as mobile phone, television, personal digital assistant, digital camera, notebook, laptop, and becomes the major display device.

Most of the liquid crystal displays on the present market are back light type liquid crystal displays, which comprise a liquid crystal display panel and a back light module. The working principle of the liquid crystal display panel is to locate liquid crystal molecules between two parallel glass substrates, and a plurality of vertical and horizontal tiny electrical wires are between the two glass substrates. The light of back light module is reflected to generate images by applying driving voltages to control whether the liquid crystal molecules to be changed directions.

Generally, the liquid crystal display panel comprises a CF (Color Filter) substrate, a TFT (Thin Film Transistor) array substrate, LC (Liquid Crystal) sandwiched between the CF substrate and TFT substrate and sealant. The formation process generally comprises: a forepart Array process (thin film, photo, etching and stripping), a middle Cell process (Lamination of the TFT substrate and the CF substrate) and a post module assembly process (Attachment of the driving IC and the printed circuit board). The forepart Array process is mainly to form the TFT substrate for controlling the movement of the liquid crystal molecules; the middle Cell process is mainly to add liquid crystal between the TFT substrate and the CF substrate; the post module assembly process is mainly the driving IC attachment and the integration of the printed circuit board. Thus, the liquid crystal molecules are driven to rotate and display pictures.

Low Temperature Poly Silicon (LTPS) is a kind of liquid crystal display technology which has been widely applied in the small, medium size electronic products. The electron mobility of the traditional amorphous silicon material is about 0.5-1.0 cm²/V.S but the electron mobility of the Low Temperature Poly Silicon can reach up to 30-300 cm²/V.S. Therefore, the Low Temperature Poly Silicon display has many advantages of high resolution, fast response speed and high aperture ratio. However, on the other hand, the volume of the LTPS semiconductor element is small and the integration is high. The manufacture process of the entire LTPS array substrate is complicated, and the production cost is higher.

FIG. 1 is a structure diagram of a portion of film layers of a Low Temperature Poly-silicon TFT substrate according to prior art. The Low Temperature Poly-silicon TFT substrate comprises a substrate 100, and a buffer layer 200, a polysilicon layer 300, a gate isolation layer 400 and a gate 500 which are sequentially located on the substrate 100 from bottom to top. In the respective film layer structure, the gate isolation layer 400 is a very important semiconductor structure. The gate isolation layer 400 is employed to be an isolation layer between the channel of the LTPS TFT and the gate 500, which is generally composed with a silicon oxide (SiOₓ) thin film 401 and a silicon nitride (SiNₓ) thin film 402, wherein the film formation quality of the silicon oxide thin film 401 has the extremely significant influence to the entire TFT electrical properties. With the different deposition methods, the film formation quality of the silicon oxide thin film can be different.

The common deposition method of the silicon oxide thin film at present is the Plasma Enhanced Chemical Vapor Deposition (PECVD). As shown in FIG. 2, the Plasma Enhanced Chemical Vapor Deposition method according to prior art is: introducing argon (Ar) into the Chemical Vapor Deposition device to generate the Argon ion (Ar+) in the RF environment of 13.5 MHz or 27.12 MHz, and employing the Ar+ to be the ion source to bombard the reaction gases, SiH₄ and N₂O under the action of the electrical field for activating the reaction gases with the bombard, and thus to make that the chemical reaction takes place on the surface (such as the polysilicon layer 300 of the Low Temperature Poly-silicon TFT substrate) of the substrate to generate the silicon oxide, and the equation of the chemical reaction is: SiH₄+N₂O→SiOₓ+N₂+H₂O, wherein the nitrogen component in N₂O makes the interface of the silicon oxide thin film 401 and the polysilicon layer 300 with more defects to cause the larger drift of the flat band voltage; second, in the PECVD process, the Ar+ is employed to be the ion source to bombard the surface of the silicon oxide thin film 401, which can easily form the interface defect and the surface damage.

Therefore, there is a need to provide a display technology field, and more particularly to a deposition method of a silicon oxide thin film and a manufacture method of a Low Temperature Poly-Silicon TFT substrate for solving the aforesaid issues.

### SUMMARY OF THE INVENTION

An objective of the present invention is to provide a deposition method of a silicon oxide thin film, in which the ultraviolet light is conducted to be the auxiliary energy of the reaction of the silicon oxide deposition to deposit the silicon oxide thin film in the plasma free environment to raise the film formation quality of the silicon oxide thin film.

Another objective of the present invention is to provide a manufacture method of a Low Temperature Poly-silicon TFT substrate. The method of generating the silicon oxide with the reaction of the organic silane gas and the oxygen in the environment irradiated by the ultraviolet light is utilized to manufacture the silicon oxide thin film in the gate isolation layer to raise the film formation quality of the silicon oxide thin film and to better promote the TFT electrical property.

For realizing the aforesaid objectives, the present invention provides a deposition method of a silicon oxide thin film, comprising steps of:

step 1, providing a chemical vapor deposition device, and the chemical vapor deposition device comprises a reaction chamber, and an ultraviolet light source is located above the reaction chamber;

step 2, positioning a substrate at a bottom of the reaction chamber, and introducing organic silane gas and oxygen into the reaction chamber, and activating the ultraviolet light source, and the oxygen is decomposed under irradiation of ultraviolet light to generate free oxygen, and a chemical reaction takes place to the organic silane gas and the free oxygen to produce silicon oxide to be deposited on the substrate to form the silicon oxide thin film.

The organic silane gas is tetraethoxysilane, tetramethylsilane, tetramethylcyclotetrasiloxane, octamethylcy-clotetrasiloxane, hexamethyl-disilazane, triethoxy-silane or trisdimethyaminosilane.

The organic silane gas is tetraethoxysilane, and an equation of a reaction taking place to the tetraethoxysilane and the oxygen under ultraviolet light to generate silicon oxide is: Si(OC₂H₅)₄+O₂→SiOₓ+2H₂O+CO₂.

Ultraviolet light emitted by the ultraviolet light source is an extreme ultraviolet light, of which a wavelength is from 10 nm to 14 nm.

The present invention further provides a manufacture method of a Low Temperature Poly-silicon TFT substrate, comprising steps of:

step 1, providing a substrate, and sequentially forming a buffer layer and a polysilicon layer on the substrate;

step 2, patterning the polysilicon layer to form a polysilicon island, and implementing P type light doping to a middle region of the polysilicon island to obtain a channel region, and implementing N type or P type heavy doping to two sides of the polysilicon island to obtain a source contact region and a drain contact region;

step 3, providing a chemical vapor deposition device, and the chemical vapor deposition device comprises a reaction chamber, and an ultraviolet light source is located above the reaction chamber;

positioning the substrate having the polysilicon island and the buffer layer at a bottom of the reaction chamber, and introducing organic silane gas and oxygen into the reaction chamber, and activating the ultraviolet light source, and the oxygen is decomposed under irradiation of ultraviolet light to generate free oxygen, and a chemical reaction takes place to the organic silane gas and the free oxygen to produce silicon oxide to be deposited on the polysilicon island and the buffer layer to form the silicon oxide thin film;

step 4, depositing a silicon nitride thin film on the silicon oxide thin film to obtain a gate isolation layer composed by stacking up the silicon oxide thin film and the silicon nitride thin film;

step 5, depositing a first metal layer on the gate isolation layer, and patterning the first metal layer to obtain a gate;

step 6, forming an interlayer insulation layer on the gate and the gate isolation layer, and patterning the interlayer insulation layer and the gate isolation layer to obtain vias corresponding above the source contact region and the drain contact region;

step 7, depositing a second metal layer on the interlayer insulation layer, and patterning the second metal layer to obtain a source and a drain, and the source and the drain respectively contact with the source contact region and the drain contact region through the vias.

The organic silane gas is tetraethoxysilane, tetramethylsilane, tetramethylcyclotetrasiloxane, octamethylcy-clotetrasiloxane, hexamethyl-disilazane, triethoxy-silane or trisdimethyaminosilane.

The organic silane gas is tetraethoxysilane, and an equation of a reaction taking place to the tetraethoxysilane and the oxygen under ultraviolet light to generate silicon oxide is: Si(OC₂H₅)₄+O₂→SiOₓ+2H₂O+CO₂.

Ultraviolet light emitted by the ultraviolet light source is an extreme ultraviolet light, of which a wavelength is from 10 nm to 14 nm.

A manufacture process of the polysilicon layer is: depositing an amorphous silicon layer on the buffer layer, and employing a low temperature crystallization process to convert the amorphous silicon layer into the polysilicon layer, and the low temperature crystallization process is Excimer Laser Annealing or Metal-induced lateral crystallization.

The substrate is a glass substrate; the buffer layer and the interlayer insulation layer are Silicon Oxide layers, Silicon Nitride layers or composite layers superimposed with Silicon Oxide layers and Silicon Nitride layers; material of the gate, the source and the drain is a stack combination of one or more of molybdenum, titanium, aluminum and copper.

The present invention further provides a manufacture method of a Low Temperature Poly-silicon TFT substrate, comprising steps of:

step 1, providing a substrate, and sequentially forming a buffer layer and a polysilicon layer on the substrate;

step 2, patterning the polysilicon layer to form a polysilicon island, and implementing P type light doping to a middle region of the polysilicon island to obtain a channel region, and implementing N type or P type heavy doping to two sides of the polysilicon island to obtain a source contact region and a drain contact region;

step 3, providing a chemical vapor deposition device, and the chemical vapor deposition device comprises a reaction chamber, and an ultraviolet light source is located above the reaction chamber;

positioning the substrate having the polysilicon island and the buffer layer at a bottom of the reaction chamber, and introducing organic silane gas and oxygen into the reaction chamber, and activating the ultraviolet light source, and the oxygen is decomposed under irradiation of ultraviolet light to generate free oxygen, and a chemical reaction takes place to the organic silane gas and the free oxygen to produce silicon oxide to be deposited on the polysilicon island and the buffer layer to form the silicon oxide thin film;

step 4, depositing a silicon nitride thin film on the silicon oxide thin film to obtain a gate isolation layer composed by stacking up the silicon oxide thin film and the silicon nitride thin film;

step 5, depositing a first metal layer on the gate isolation layer, and patterning the first metal layer to obtain a gate;

step 6, forming an interlayer insulation layer on the gate and the gate isolation layer, and patterning the interlayer insulation layer and the gate isolation layer to obtain vias corresponding above the source contact region and the drain contact region;

step 7, depositing a second metal layer on the interlayer insulation layer, and patterning the second metal layer to obtain a source and a drain, and the source and the drain respectively contact with the source contact region and the drain contact region through the vias;

wherein the organic silane gas is tetraethoxysilane, tetramethylsilane, tetramethylcyclotetrasiloxane, octamethylcy-clotetrasiloxane, hexamethyl-disilazane, triethoxy-silane or trisdimethyaminosilane;

wherein ultraviolet light emitted by the ultraviolet light source is an extreme ultraviolet light, of which a wavelength is from 10 nm to 14 nm.

The benefits of the present invention are: the present invention provides a deposition method of a silicon oxide thin film. The ultraviolet light is conducted to be the auxiliary energy of the reaction of the silicon oxide deposition. The ultra violet light is utilized to decompose the oxygen to be free oxygen, which reacts with the organic silane gas to generate silicon oxide, and thus to be deposited to form the silicon oxide thin film in the plasma free environment to prevent the surface of the silicon oxide thin film from the interface defect and surface damage formed by being impacted with the high energy plasma to raise the film formation quality of the silicon oxide thin film. The present invention provides the manufacture method of the Low Temperature Poly-silicon TFT substrate. The method of generating the silicon oxide with the reaction of the organic silane gas and the oxygen in the environment irradiated by the ultraviolet light is utilized to manufacture the silicon oxide thin film in the gate isolation layer to prevent the interface defect and surface damage to the surface of the silicon oxide caused by the plasma in the plasma enhanced chemical vapor deposition method according to prior art, and thus to raise the film formation quality of the silicon oxide thin film and to better promote the TFT electrical property.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structure diagram of a portion of film layers of a Low Temperature Poly-silicon TFT substrate according to prior art;

FIG. 2 is a diagram of a plasma enhanced chemical vapor deposition method of the silicon oxide according to prior art;

FIG. 3 is a diagram of a deposition method of a silicon oxide thin film according to the present invention;

FIG. 4 is a diagram of the step 1 in the manufacture method of the Low Temperature Poly-silicon TFT substrate according to the present invention;

FIG. 5 is a diagram of the step 2 in the manufacture method of the Low Temperature Poly-silicon TFT substrate according to the present invention;

FIG. 6 is a diagram of the step 3 in the manufacture method of the Low Temperature Poly-silicon TFT substrate according to the present invention;

FIG. 7 is a diagram of the step 4 in the manufacture method of the Low Temperature Poly-silicon TFT substrate according to the present invention;

FIG. 8 is a diagram of the step 5 in the manufacture method of the Low Temperature Poly-silicon TFT substrate according to the present invention;

FIG. 9 is a diagram of the step 6 in the manufacture method of the Low Temperature Poly-silicon TFT substrate according to the present invention;

FIG. 10 is a diagram of the step 7 in the manufacture method of the Low Temperature Poly-silicon TFT substrate according to the present invention.

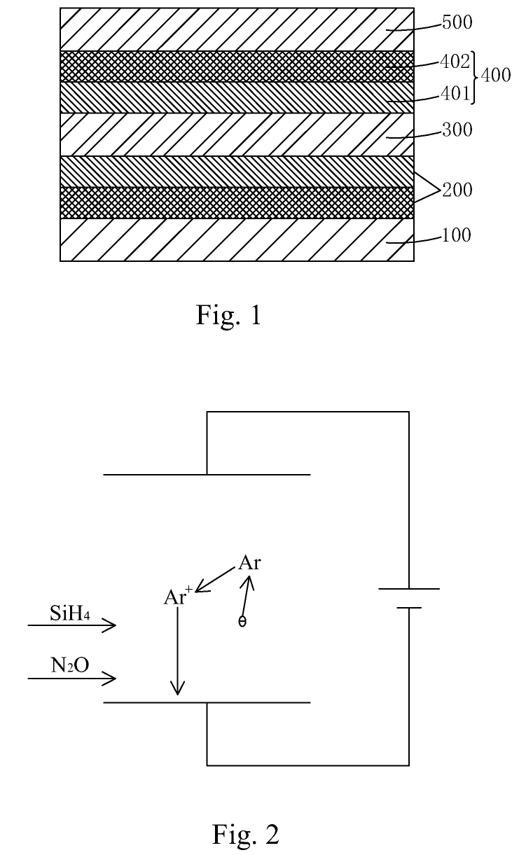

### DETAILED DESCRIPTION OF PREFERRED EMBODIMENTS

For better explaining the technical solution and the effect of the present invention, the present invention will be further described in detail with the accompanying drawings and the specific embodiments.

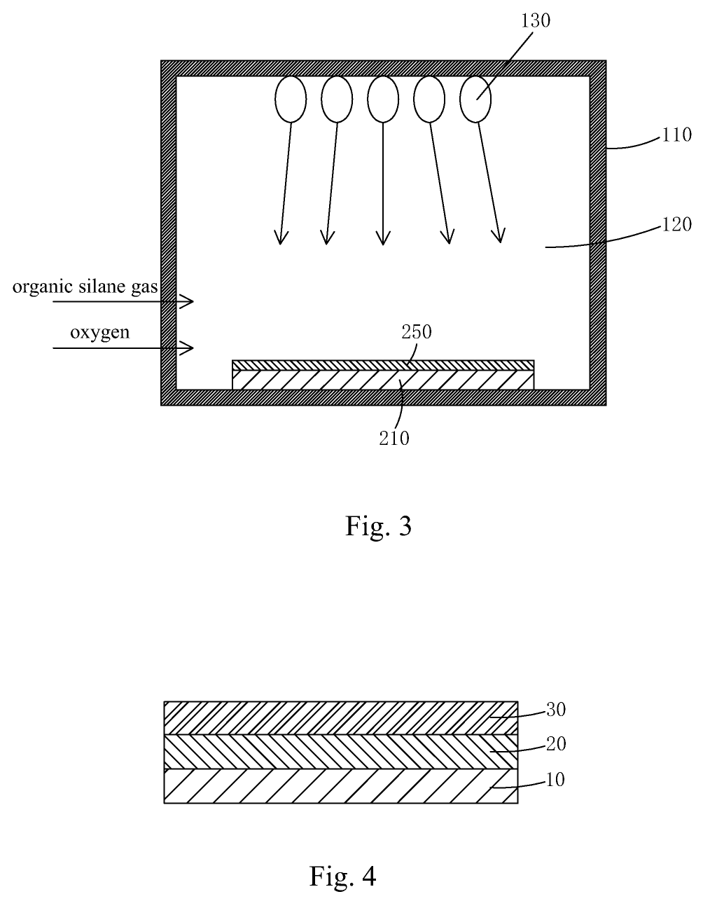

Please refer to FIG. 3, the present invention provides a deposition method of a silicon oxide thin film, comprising steps of:

step 1, providing a chemical vapor deposition device 110, and the chemical vapor deposition device 110 comprises a reaction chamber 120, and an ultraviolet light source 130 is located above the reaction chamber 120.

step 2, positioning a substrate 210 at a bottom of the reaction chamber 120, and introducing organic silane gas and oxygen into the reaction chamber 120, and activating the ultraviolet light source 130, and the oxygen is decomposed under irradiation of ultraviolet light to generate free oxygen, and a chemical reaction takes place to the organic silane gas and the free oxygen to produce silicon oxide (SiOₓ) to be deposited on the substrate 210 to form the silicon oxide thin film 250.

Specifically, the organic silane gas can be tetraethoxysilane (TEOS, chemical formula: Si(OC₂H₅)₄), tetramethylsilane (TMS, chemical formula: Si(CH₃)₄), tetramethylcyclotetrasiloxane (TMCTS), octamethylcy-clotetrasiloxane (OMCTS), hexamethyl-disilazane (HMDS), triethoxy-silane (SiH(OC₂H₅)₃) or trisdimethyaminosilane SiH(N(CH₃)₂)₃.

Preferably, the organic silane gas is tetraethoxysilane, and an equation of a reaction taking place to the tetraethoxysilane and the oxygen under ultraviolet light to generate silicon oxide is: Si(OC₂H₅)₄+O₂→SiOₓ+2H₂O+CO₂, wherein x=1 or 2.

Preferably, ultraviolet light emitted by the ultraviolet light source 130 is an extreme ultraviolet light (EUV), of which a wavelength is from 10 nm to 14 nm. Because the wavelength of the extreme ultraviolet light (EUV) is shorter, and the energy is higher, which can allow the organic silane gas involved with the reaction can be enormously decomposed and activated in a short time to shorten the reaction duration.

Preferably, the thickness of the silicon oxide thin film 250 obtained in the step 2 is 500-1000 Å.

Please refer to FIGS. 4-10. The present invention further provides a manufacture method of a Low Temperature Poly-silicon TFT substrate, comprising steps of:

step 1, as shown in FIG. 4, providing a substrate 10, and sequentially forming a buffer layer 20 and a polysilicon layer 30 on the substrate 10.

Specifically, a manufacture process of the polysilicon layer 30 is: depositing an amorphous silicon layer on the buffer layer 20, and employing a low temperature crystallization process to convert the amorphous silicon layer into the polysilicon layer 30, and the low temperature crystallization process can be Excimer Laser Annealing or Metal-induced lateral crystallization.

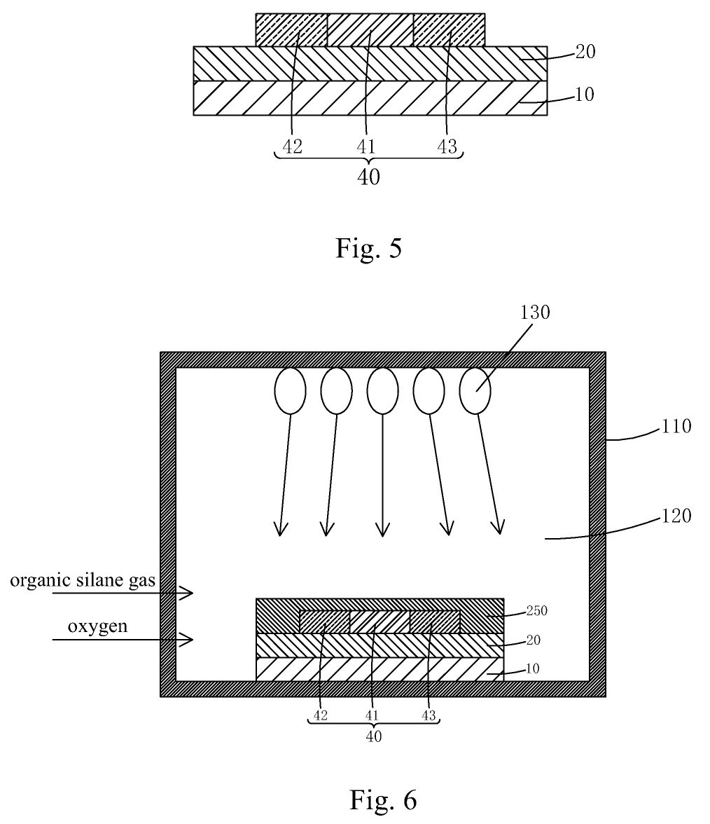

step 2, as shown in FIG. 5, patterning the polysilicon layer 30 to form a polysilicon island 40, and implementing P type light doping to a middle region of the polysilicon island 40 to obtain a channel region 41, and implementing N type or P type heavy doping to two sides of the polysilicon island 41 to obtain a source contact region 42 and a drain contact region 43.

Specifically, the ion doped in the N type doping region is phosphorus ion or arsenic ion; the ion doped in the P type doping region is boron ion or gallium ion.

step 3, as shown in FIG. 6, providing a chemical vapor deposition device 110, and the chemical vapor deposition device 110 comprises a reaction chamber 120, and an ultraviolet light source 130 is located above the reaction chamber 120;

positioning the substrate 10 having the polysilicon island 40 and the buffer layer 20 at a bottom of the reaction chamber 120, and introducing organic silane gas and oxygen into the reaction chamber 120, and activating the ultraviolet light source 130, and the oxygen is decomposed under irradiation of ultraviolet light to generate free oxygen, and a chemical reaction takes place to the organic silane gas and the free oxygen to produce silicon oxide (SiOₓ) to be deposited on the polysilicon island 40 and the buffer layer 20 to form the silicon oxide thin film 250.

Specifically, the organic silane gas can be tetraethoxysilane (TEOS, chemical formula: Si(OC₂H₅)₄), tetramethylsilane (TMS, chemical formula: Si(CH₃)₄), tetramethylcyclotetrasiloxane (TMCTS), octamethylcy-clotetrasiloxane (OMCTS), hexamethyl-disilazane (HMDS), triethoxy-silane (SiH(OC₂H₅)₃) or trisdimethyaminosilane SiH(N(CH₃)₂)₃.

Preferably, the organic silane gas is tetraethoxysilane, and an equation of a reaction taking place to the tetraethoxysilane and the oxygen under ultraviolet light to generate silicon oxide is: Si(OC₂H₅)₄+O₂→SiOₓ+2H₂O+CO₂, wherein x=1 or 2.

Preferably, ultraviolet light emitted by the ultraviolet light source 130 is an extreme ultraviolet light (EUV), of which a wavelength is from 10 nm to 14 nm. Because the wavelength of the extreme ultraviolet light (EUV) is shorter, and the energy is higher, which can allow the organic silane gas involved with the reaction can be enormously decomposed and activated in a short time to shorten the reaction duration.

Preferably, the thickness of the silicon oxide thin film 250 obtained in the step 2 is 500-1000 Å.

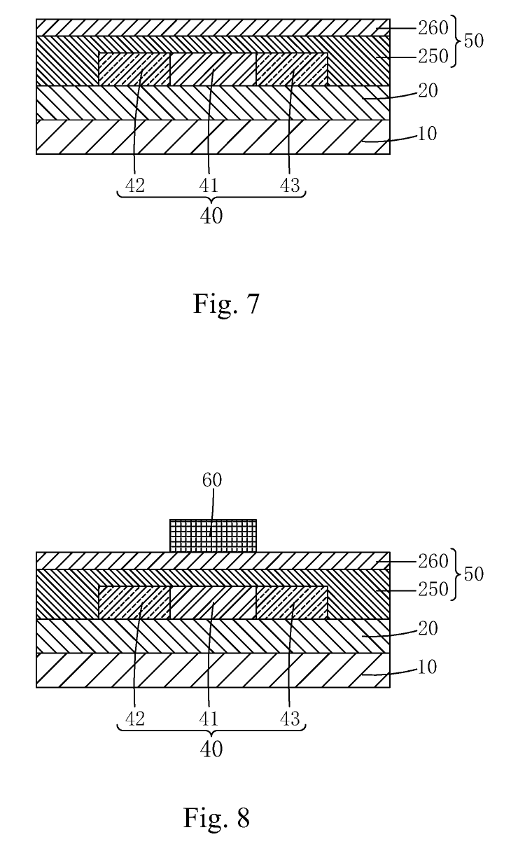

step 4, as shown in FIG. 7, depositing a silicon nitride thin film 260 on the silicon oxide thin film 250 to obtain a gate isolation layer 50 composed by stacking up the silicon oxide thin film 250 and the silicon nitride thin film 260.

step 5, as shown in FIG. 8, depositing a first metal layer on the gate isolation layer 50, and patterning the first metal layer to obtain a gate 60.

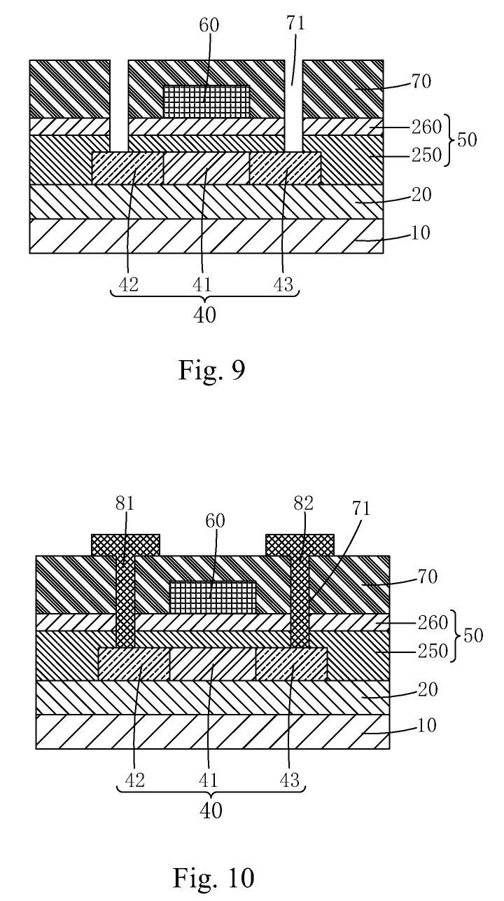

step 6, as shown in FIG. 9, forming an interlayer insulation layer 70 on the gate 60 and the gate isolation layer 50, and patterning the interlayer insulation layer 70 and the gate isolation layer 50 to obtain vias 71 corresponding above the source contact region 42 and the drain contact region 43.

step 8, as shown in FIG. 10, depositing a second metal layer on the interlayer insulation layer 70, and patterning the second metal layer with a photolithographic process to obtain a source 81 and a drain 82, and the source 81 and the drain 82 respectively contact with the source contact region 42 and the drain contact region 43 on the polysilicon island 40 through the vias 71.

Specifically, the substrate 10 is a glass substrate.

Specifically, the buffer layer 20 and the interlayer insulation layer 70 can be Silicon Oxide layers, Silicon Nitride layers or composite layers superimposed with Silicon Oxide (SiOₓ) layers and Silicon Nitride (SiNₓ) layers.

Specifically, material of the gate 60, the source 81 and the drain 82 can be a stack combination of one or more of molybdenum (Mo), titanium (Ti), aluminum (Al) and copper (Cu).

In conclusion, the present invention provides a deposition method of a silicon oxide thin film. The ultraviolet light is conducted to be the auxiliary energy of the reaction of the silicon oxide deposition. The ultra violet light is utilized to decompose the oxygen to be free oxygen, which reacts with the organic silane gas to generate silicon oxide, and thus to be deposited to form the silicon oxide thin film in the plasma free environment to prevent the surface of the silicon oxide thin film from the interface defect and surface damage formed by being impacted with the high energy plasma to raise the film formation quality of the silicon oxide thin film. The present invention provides the manufacture method of the Low Temperature Poly-silicon TFT substrate. The method of generating the silicon oxide with the reaction of the organic silane gas and the oxygen in the environment irradiated by the ultraviolet light is utilized to manufacture the silicon oxide thin film in the gate isolation layer to prevent the interface defect and surface damage to the surface of the silicon oxide caused by the plasma in the plasma enhanced chemical vapor deposition method according to prior art, and thus to raise the film formation quality of the silicon oxide thin film and to better promote the TFT electrical property.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A deposition method of a silicon oxide thin film, comprising steps of:
step 1, providing a chemical vapor deposition device, and the chemical vapor deposition device comprises a reaction chamber, and an ultraviolet light source is located above the reaction chamber;
step 2, positioning a substrate at a bottom of the reaction chamber, and introducing organic silane gas and oxygen into the reaction chamber, and activating the ultraviolet light source, and the oxygen is decomposed under irradiation of ultraviolet light to generate free oxygen, and a chemical reaction takes place to the organic silane gas and the free oxygen to produce silicon oxide to be deposited on the substrate to form the silicon oxide thin film.

2. The deposition method of the silicon oxide thin film according to claim 1, wherein the organic silane gas is tetraethoxysilane, tetramethylsilane, tetramethylcyclotetrasiloxane, octamethylcy-clotetrasiloxane, hexamethyl-disilazane, triethoxy-silane or trisdimethyaminosilane.

3. The deposition method of the silicon oxide thin film according to claim 2, wherein the organic silane gas is tetraethoxysilane, and an equation of a reaction taking place to the tetraethoxysilane and the oxygen under ultraviolet light to generate silicon oxide is: Si(OC₂H₅)₄+O₂→SiOₓ+2H₂O+CO₂.

4. The deposition method of the silicon oxide thin film according to claim 1, wherein ultraviolet light emitted by the ultraviolet light source is an extreme ultraviolet light, of which a wavelength is from 10 nm to 14 nm.

5. A manufacture method of a Low Temperature Poly-silicon TFT substrate, comprising steps of:
step 1, providing a substrate, and sequentially forming a buffer layer and a polysilicon layer on the substrate;
step 2, patterning the polysilicon layer to form a polysilicon island, and implementing P type light doping to a middle region of the polysilicon island to obtain a channel region, and implementing N type or P type heavy doping to two sides of the polysilicon island to obtain a source contact region and a drain contact region;
step 3, providing a chemical vapor deposition device, and the chemical vapor deposition device comprises a reaction chamber, and an ultraviolet light source is located above the reaction chamber;
positioning the substrate having the polysilicon island and the buffer layer at a bottom of the reaction chamber, and introducing organic silane gas and oxygen into the reaction chamber, and activating the ultraviolet light source, and the oxygen is decomposed under irradiation of ultraviolet light to generate free oxygen, and a chemical reaction takes place to the organic silane gas and the free oxygen to produce silicon oxide to be deposited on the polysilicon island and the buffer layer to form the silicon oxide thin film;
step 4, depositing a silicon nitride thin film on the silicon oxide thin film to obtain a gate isolation layer composed by stacking up the silicon oxide thin film and the silicon nitride thin film;
step 5, depositing a first metal layer on the gate isolation layer, and patterning the first metal layer to obtain a gate;
step 6, forming an interlayer insulation layer on the gate and the gate isolation layer, and patterning the interlayer insulation layer and the gate isolation layer to obtain vias corresponding above the source contact region and the drain contact region;
step 7, depositing a second metal layer on the interlayer insulation layer, and patterning the second metal layer to obtain a source and a drain, and the source and the drain respectively contact with the source contact region and the drain contact region through the vias.

6. The manufacture method of the Low Temperature Poly-silicon TFT substrate according to claim 5, wherein the organic silane gas is tetraethoxysilane, tetramethylsilane, tetramethylcyclotetrasiloxane, octamethylcy-clotetrasiloxane, hexamethyl-disilazane, triethoxy-silane or trisdimethyaminosilane.

7. The manufacture method of the Low Temperature Poly-silicon TFT substrate according to claim 6, wherein the organic silane gas is tetraethoxysilane, and an equation of a reaction taking place to the tetraethoxysilane and the oxygen under ultraviolet light to generate silicon oxide is: Si(OC₂H₅)₄+O₂→SiOₓ+2H₂O+CO₂.

8. The manufacture method of the Low Temperature Poly-silicon TFT substrate according to claim 5, wherein ultraviolet light emitted by the ultraviolet light source is an extreme ultraviolet light, of which a wavelength is from 10 nm to 14 nm.

9. The manufacture method of the Low Temperature Poly-silicon TFT substrate according to claim 5, wherein a manufacture process of the polysilicon layer is: depositing an amorphous silicon layer on the buffer layer, and employing a low temperature crystallization process to convert the amorphous silicon layer into the polysilicon layer, and the low temperature crystallization process is Excimer Laser Annealing or Metal-induced lateral crystallization.

10. The manufacture method of the Low Temperature Poly-silicon TFT substrate according to claim 5, wherein the substrate is a glass substrate; the buffer layer and the interlayer insulation layer are Silicon Oxide layers, Silicon Nitride layers or composite layers superimposed with Silicon Oxide layers and Silicon Nitride layers; material of the gate, the source and the drain is a stack combination of one or more of molybdenum, titanium, aluminum and copper.

11. A manufacture method of a Low Temperature Poly-silicon TFT substrate, comprising steps of:
step 1, providing a substrate, and sequentially forming a buffer layer and a polysilicon layer on the substrate;
step 2, patterning the polysilicon layer to form a polysilicon island, and implementing P type light doping to a middle region of the polysilicon island to obtain a channel region, and implementing N type or P type heavy doping to two sides of the polysilicon island to obtain a source contact region and a drain contact region;
step 3, providing a chemical vapor deposition device, and the chemical vapor deposition device comprises a reaction chamber, and an ultraviolet light source is located above the reaction chamber;
positioning the substrate having the polysilicon island and the buffer layer at a bottom of the reaction chamber, and introducing organic silane gas and oxygen into the reaction chamber, and activating the ultraviolet light source, and the oxygen is decomposed under irradiation of ultraviolet light to generate free oxygen, and a chemical reaction takes place to the organic silane gas and the free oxygen to produce silicon oxide to be deposited on the polysilicon island and the buffer layer to form the silicon oxide thin film;
step 4, depositing a silicon nitride thin film on the silicon oxide thin film to obtain a gate isolation layer composed by stacking up the silicon oxide thin film and the silicon nitride thin film;
step 5, depositing a first metal layer on the gate isolation layer, and patterning the first metal layer to obtain a gate;
step 6, forming an interlayer insulation layer on the gate and the gate isolation layer, and patterning the interlayer insulation layer and the gate isolation layer to obtain vias corresponding above the source contact region and the drain contact region;
step 7, depositing a second metal layer on the interlayer insulation layer, and patterning the second metal layer to obtain a source and a drain, and the source and the drain respectively contact with the source contact region and the drain contact region through the vias;
wherein the organic silane gas is tetraethoxysilane, tetramethylsilane, tetramethylcyclotetrasiloxane, octamethylcy-clotetrasiloxane, hexamethyl-disilazane, triethoxy-silane or trisdimethyaminosilane;
wherein ultraviolet light emitted by the ultraviolet light source is an extreme ultraviolet light, of which a wavelength is from 10 nm to 14 nm.

12. The manufacture method of the Low Temperature Poly-silicon TFT substrate according to claim 11, wherein the organic silane gas is tetraethoxysilane, and an equation of a reaction taking place to the tetraethoxysilane and the oxygen under ultraviolet light to generate silicon oxide is: Si(OC₂H₅)₄+O₂→SiOₓ+2H₂O+CO₂.

13. The manufacture method of the Low Temperature Poly-silicon TFT substrate according to claim 11, wherein a manufacture process of the polysilicon layer is: depositing an amorphous silicon layer on the buffer layer, and employing a low temperature crystallization process to convert the amorphous silicon layer into the polysilicon layer, and the low temperature crystallization process is Excimer Laser Annealing or Metal-induced lateral crystallization.

14. The manufacture method of the Low Temperature Poly-silicon TFT substrate according to claim 11, wherein the substrate is a glass substrate; the buffer layer and the interlayer insulation layer are Silicon Oxide layers, Silicon Nitride layers or composite layers superimposed with Silicon Oxide layers and Silicon Nitride layers; material of the gate, the source and the drain is a stack combination of one or more of molybdenum, titanium, aluminum and copper.
